(19) United States
(12) Patent Application Publication
(10) Pub. No.: US 2026/0136553 A1
(43) Pub. Date: May 14, 2026

(54) 3-DIMENSIONAL SEMICONDUCTOR MEMORY DEVICE WITH ALTERNATIVE MEMORY CHANNEL LAYER AND METHOD FOR FORMING THE SAME

(71) Applicant: SK hynix Inc., Gyeonggi-do (KR)

(72) Inventors: Jungdal CHOI, San Jose, CA (US); Agus TJANDRA, San Jose, CA (US); Sung-Taeg KANG, San Jose, CA (US)

(21) Appl. No.: 18/945,525

(22) Filed: Nov. 13, 2024

(51) Int. Cl. H10B 43/27; H10B 43/35

(52) U.S. Cl. CPC H10B 43/27; H10B 43/35

(57) ABSTRACT

A method for forming a 3D memory device is provided. The method includes providing a stacked structure including oxide layers and nitride layers alternately stacked together; forming a through hole in the stacked structure; forming a memory storage structure on a sidewall of the through hole in the stacked structure; and selectively forming a channel layer of a transition metal di-chalcogenide on the memory storage structure using an inhibition layer.

### 1. FIELD OF THE INVENTION

The present invention generally relates to the formation of channel layers in transistors and, more particularly, to the formation of channel layers in NAND memory cells.

### 2. BACKGROUND

The scaling of integrated circuits to smaller and smaller features in the semiconductor industry has increased densities of semiconductor chips. For example, shrinking transistor size permitted the incorporation of an increased number of memory or logic devices on a chip, lending to the fabrication of products with increased capacity.

In 3-dimensional (3D) NAND, the memory cells are stacked vertically, and typically a polycrystalline silicon (poly-Si) channel is commonly used. In general, a channel contains material forming a pathway through which charge carriers (electrons, or holes) move between the source and drain in a transistor. Vertical stacking requires the channel to pass through multiple layers. As semiconductor technology advances, it is necessary to continue driving process innovation to deliver superior device performance. For example, cell density has been continuously increased through lateral and vertical scaling.

It is in this context that the present invention arises.

### SUMMARY

One embodiment of the present invention provides a method for forming a 3D semiconductor memory device. The method may include providing a stacked structure including oxide layers and nitride layers alternately stacked together; forming a through hole in the stacked structure; forming a memory storage structure on a sidewall of the through hole in the stacked structure; and forming a channel layer of a transition metal di-chalcogenide on the memory storage structure using an inhibition layer.

Another embodiment of the present invention provides a method for forming a 3D semiconductor memory device. The 3D semiconductor memory device may include a stacked dielectric structure having a through hole; a memory storage structure disposed on a sidewall of the through hole in the stacked structure; a channel layer of a semiconductive transition metal di-chalcogenide disposed on the memory storage structure; and an inhibition layer disposed on a part of the channel layer.

These and other features and advantages of the present invention will become apparent to those skilled in the art of the invention from the following detailed description in conjunction with the following drawings.

### BRIEF DESCRIPTION OF THE DRAWINGS

FIG. 1 illustrates a transition metal di-chalcogenide (TMD) “macaroni” channel according to one embodiment of the present invention.

FIG. 2 illustrates a TMD “full” channel according to another embodiment of the present invention.

FIG. 3A illustrates a TMD selective deposition process according to another embodiment of the present invention.

FIG. 3B illustrates a precursor for another TMD selective deposition process according to one embodiment of the present invention.

FIG. 3C illustrates the beginning of a full channel TMD selective deposition process according to one embodiment of the present invention.

FIG. 3D illustrates a completion of the full channel TMD selective deposition process according another embodiment of the present invention.

FIG. 4 illustrates a TMD channel connected to a bit line contact with poly-silicon plug in accordance with embodiments of the present invention.

FIG. 5 is a flowchart illustrating one method for forming a memory structure in accordance with embodiments of the present invention

FIG. 6 is a schematic diagram illustrating a multi-dimensional memory device in accordance with embodiments of the present invention.

FIG. 7 is a schematic diagram illustrating a stacked memory structure in accordance with embodiments of the present invention.

FIG. 8 is a schematic diagram illustrating another stacked memory structure in accordance with embodiments of the present invention.

### DETAILED DESCRIPTION

Various embodiments of the present invention will be described in greater detail with reference to the accompanying drawings. The drawings are schematic illustrations of various embodiments (and intermediate structures). As such, variations from the configurations and shapes of the illustrations as a result, for example, of manufacturing techniques and/or tolerances, are to be expected. Thus, the described embodiments should not be construed as being limited to the particular configurations and shapes illustrated herein but may include deviations in configurations and shapes which do not depart from the spirit and scope of the present invention as defined in the appended claims.

The present invention is described herein with reference to cross-section and/or plan illustrations of idealized embodiments of the present invention. However, embodiments of the present invention should not be construed as limiting the inventive concept. Although a few embodiments of the present invention will be shown and described, it will be appreciated by those of ordinary skill in the art that changes may be made in these embodiments without departing from the principles and spirit of the present invention.

It will be understood that, although the terms “first”, “second”, “third”, and so on may be used herein to describe various elements, these elements are not limited by these terms. These terms are used to distinguish one element from another element. Thus, a first element described below could also be termed as a second or third element without departing from the spirit and scope of the present invention.

It will be further understood that when an element is referred to as being “connected to”, or “coupled to” another element, it may be directly on, connected to, or coupled to the other element, or one or more intervening elements may be present. Furthermore, the connection/coupling may not be limited to a physical connection but may also include a non-physical connection, e.g., a wireless connection.

In addition, it will also be understood that when an element is referred to as being “between” two elements, it may be the only element between the two elements, or one or more intervening elements may also be present.

When a first element is referred to as being “over” a second element, it not only refers to a case where the first element is formed directly on the second element but also a case where a third element exists between the first element and the second element. When a first element is referred to as being “on” a second element, it refers to a case where the first element is formed directly or indirectly on the second layer or the substrate.

It should be understood that the drawings are simplified schematic illustrations of the described devices and may not include well known details for avoiding obscuring the features of the invention.

It should also be noted that features present in one embodiment may be used with one or more features of another embodiment without departing from the scope of the invention.

It is further noted, that in the various drawings, like reference numbers designate like elements.

As used herein, singular forms are intended to include the plural forms as well, unless the context clearly indicates otherwise.

One of the scaling challenges for increasing the number of memory or logic devices on a chip is related to channel scaling, which typically leads to short channel effects where the channel length is comparable to the depletion layer widths of the source and drain junction. To mitigate the short channel effects, poly-silicon channel thicknesses have been scaled down as the channel length is reduced. The present inventors have recognized that this scaling down of the poly-silicon channel thickness results in lower mobility and lower cell string currents (between a string of memory cells connected together with a common source select transistor SST and a common drain select transistor DST) due to (a) the higher resistance of the thinner poly-silicon channel and (b) the threshold voltage instabilities of the poly-silicon because of the presence of dangling bonds on the surface of the poly-silicon material.

In one embodiment of the present disclosure, alternative channel materials such as 2D or transition metal di-chalcogenides (TMD) are used that (unlike poly-silicon) can maintain electrically conductive properties (e.g., high mobility and high cell string current) when scaled down in size. TMDs have a unique two-dimensional (2D) structure where the transition metal is sandwiched between two layers of chalcogen atoms. These layers are bonded strongly by covalent bonds within the plane but are held together with weaker van der Waals forces between the layers. In the present disclosure, TMDs having semiconducting properties may be used. For example, TMDs suitable for the present invention include molybdenum disulfide (MoS₂), Tungsten disulfide (WS₂), molybdenum diselenide (MoSe₂), molybdenum telluride (MoTe₂), tin sulfide (SnS₂), tin selenide (SnSe₂), hafnium sulfide (HfS₂), hafnium selenide (HfSe₂), platinum sulfide (PtS₂), platinum selenide (PtSe), platinum telluride (PtTe₂) and Tungsten diselenide (WSe₂). TMDs can be deposited using metal organic chemical vapor deposition (MOCVD), furnace CVD, atomic layer deposition (ALD), plasma enhanced atomic layer deposition (PEALD), or thermal atomic layer deposition, and/or with selective epitaxial growth or selective deposition (using an inhibition layer).

Besides higher mobility, TMD materials also have other advantages in terms of (a) lower thickness scaling made possible due to the pristine surfaces of the TMD with no dangling bonds and (b) lower deposition temperatures which simultaneously allows penta-level cell (PLC) NAND or Multi-Site Cell (MSC) technology to be realized without impacting critical dimensions of other memory stack layers.

### TMD Macaroni Channel Through Selected Deposition

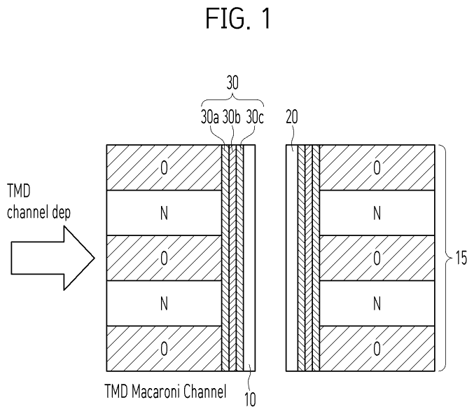

Referring now to FIG. 1, a TMD macaroni channel structure 10 is illustrated. The term “macaroni” as used herein refers to the hollow tube structure of the channel 10 which resembles the shape of a macaroni noodle. The TMD macaroni channel structure 10 may be formed via a selective deposition of the TMD layer on sidewalls of a stacked structure 15 depicted in FIG. 1.

In 3D NAND, the memory cells are stacked vertically, and typically a polycrystalline silicon (poly-Si) channel is commonly used. This vertical stacking requires the channel to pass through multiple layers. The TMD macaroni channel structure 10 extends (preferably but not necessarily) perpendicularly through the stacked structure 15 of alternating oxide and nitride layers O and N, respectively. After forming the channel structure, nitride layers in the stacked structure 15 are removed, and metal layers (i.e., word lines) are formed in regions where the nitride layers were removed from.

In one embodiment, the TMD macaroni channel structure 10 may be formed using etching to form a channel hole “CH” passing through the “ON” stack (as is known in the art). In a typical semiconductor device, a plurality of channel holes CH may be formed spaced apart from each other, forming various patterns as may be needed. Each of the channel holes CH may have a circular, oval, or polygonal shape.

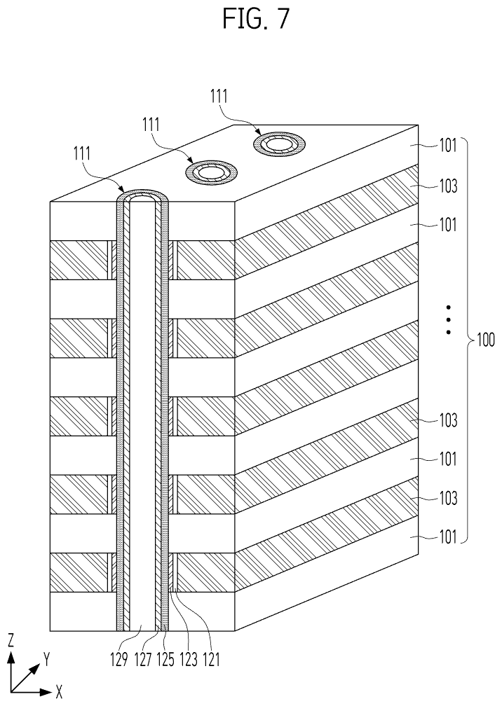

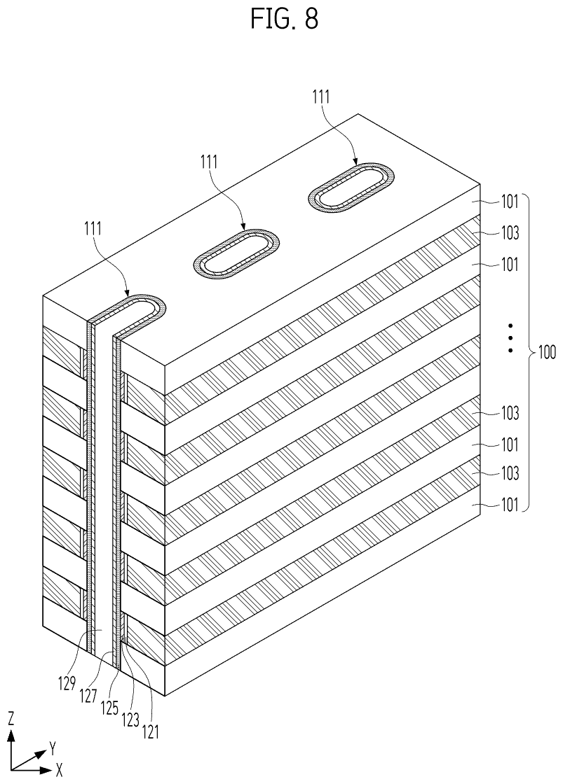

The TMD macaroni channel structure 10 includes a TMD channel layer 20 formed conformally on a vertical multi-layer structure 30 (30a, 30b, and 30c) covering the sidewall of the channel hole CH. The multi-layer structure 30 may correspond to a memory storage structure (or a memory layer), and may include a first, second, and third layers 30a, 30b, and 30c, respectively, which are sequentially formed on the sidewall of the channel hole in the stack 15. The first layer 30a may be a blocking insulating layer and be formed directly on the sidewall of stack 15. The second layer 30b may be a data storage layer (i.e., a charge trap layer) and is formed on the first layer 30a. The first layer 30a and the second layer 30b may be formed in a pocket 25 in between oxide layers in stack 15. The third layer 30c is formed on the second layer and may be a tunnelling layer. The first, second, and third layers 30a, 30b, and 30c correspond to 121, 123, and 125 of FIGS. 7 and 8.

The TMD layer 20 may be made of any suitable semiconductive TMD material including for example, molybdenum disulfide (MoS₂), Tungsten disulfide (WS₂), molybdenum diselenide (MoSe₂), and Tungsten diselenide (WSe₂).

Thus, one embodiment of the present disclosure (as described above) utilizes semiconductive transition metal di-chalcogenides (TMD) as channel material for maintaining electrical properties of high mobility and high cell string current in memory cells.

### TMD Full Channel Through Selective Epitaxial Growth

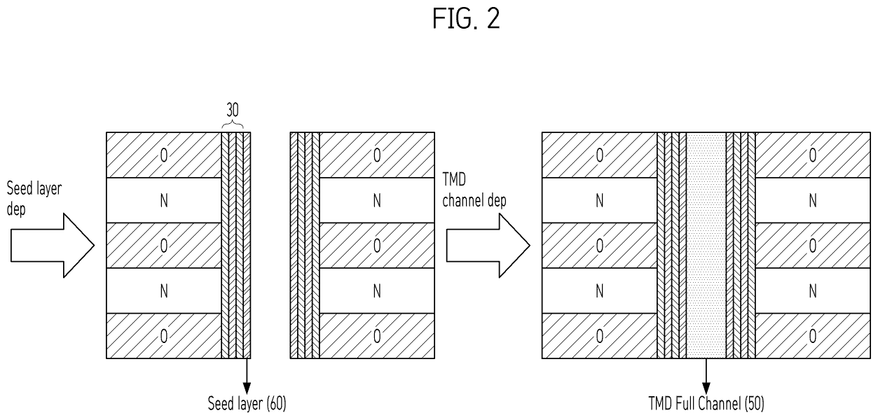

Referring now to FIG. 2, a TMD full channel 50 is illustrated. The TMD full channel may be formed via selective epitaxial growth of the TMD. FIG. 2 is also not a depiction of a final memory structure but that of an intermediate structure. After forming the TMD full channel, nitride layers in the stacked structure 15 are removed, and metal layers (i.e., word lines) are formed in regions where the nitride layers were removed from.

As shown in FIG. 2, after the multi-layer structure 30 described above is formed, on the sidewall of the channel hole in the stack 15, a seed layer 60 is formed on the multi-layer structure (i.e., memory storage structure 30). As used herein, the seed layer 60 is the first deposited layer of TMD on the memory storage structure 30. With the seed layer deposited, the TMD nucleates on the sidewall and then grows (due to the surface free energy of the TMD) on itself until the TMD channel is formed. For a lower number of nucleation sites, the resulting grain size of the TMD will be higher. The resulting TMD channel layer may be the TMD macaroni channel 10 as shown in FIG. 1 or the TMD full channel 50 as shown in FIG. 2. The seed layer 60 of FIG. 2 may be referred to as a TMD grain-size control layer. Other ways to control grain growth and grain size of the resultant TMD layer which are suitable for the present disclosure may include a) using an encapsulation layer of for example boron nitride or b) creating a relatively small confinement space with replacement channel flow prior to TMD deposition to force the grain growth in a preferred direction.

### TMD Selective Deposition Using Inhibition Layer

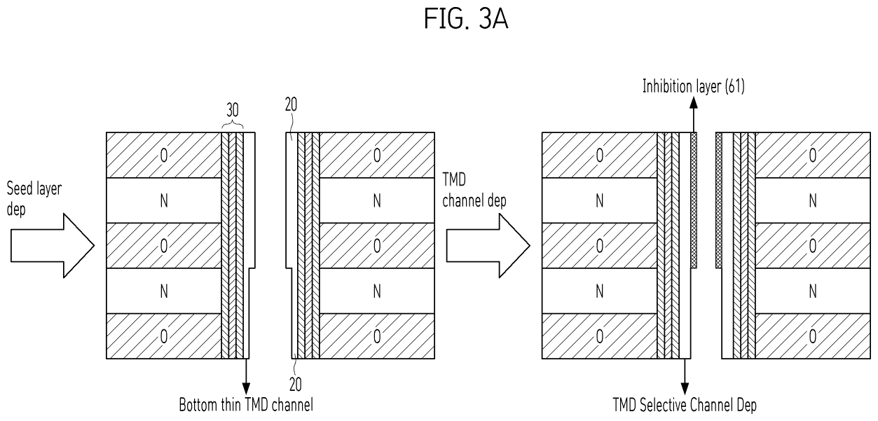

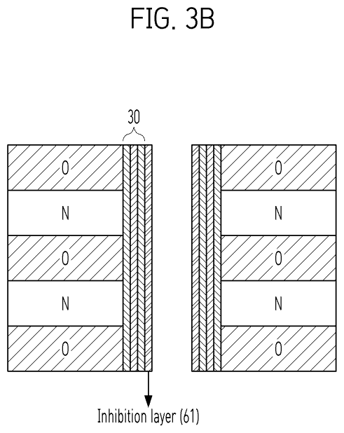

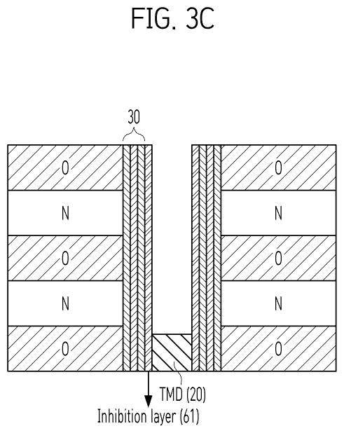

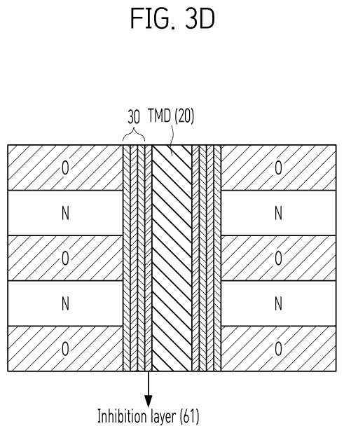

In another embodiment of the present disclosure, there is provided a method for forming a TMD channel layer in a channel hole of a 3D stack of a semiconductor device, the method including selectively depositing a TMD material on the memory storage structure 30 formed on (or included at least partially in) the stack 15 shown in FIG. 3A. In this embodiment, an inhibition layer 61 in FIG. 3A may completely cover certain areas of the memory hole sidewall and thereby can prevent deposition of a TMD channel layer on those areas of the memory hole sidewall having the inhibition layer 61 and can permit selective channel deposition on areas not covered by the inhibition layer 61. This capability can optimize channel sidewall deposition uniformity in cases where there are critical dimension (CD) variations from top to bottom due to etch processing used.

In one embodiment of the present disclosure, the inhibition layer 61 may include one or more materials containing N or other self-assembled monolayers like octadecyltrichlorosilane (ODTS) or small molecules inhibitors like dimethlyamino-trimethysilane (DMA-TMS). The inhibition layers would be typically deposited using an atomic layer deposition (ALD) process. Some examples of nitrogen containing inhibition layers include but are not limited to trimethylamine, hexamethyldisilazane (HMDS), and amide based or nitrile based molecules.

Referring now to FIG. 3A, a TMD selected deposition process is illustrated which uses inhibition to compensate for integration challenges such as high aspect ratio (HAR) memory hole and the like. While the present disclosure is not limited to specific HARs, in general, the aspect ratios can range from 20:1 to 200:1, and can be greater than 100:1.

Here, as shown in FIG. 3A (on left-side), without precautions, there is a tendency of the bottom of the opening to have a thinner TMD channel layer than at the top due to the high aspect ratio of the channel hole. In one embodiment of the present disclosure, an inhibition layer 61 is formed on the top of the TMD channel layer 20. In one example, the inhibition layer 61 would passivate the surface at the top of the TMD channel layer 20 (making this surface hydrophobic or hydrophilic), and thereby could block the adsorption of TMD precursors and prevent deposition in this area. The inhibition layer 61 of FIG. 3A may be referred to as a TMD deposition-preventing layer. After deposition of the inhibition layer 61, deposition of a TMD channel layer 20 continues (as on right side of FIG. 3A) resulting in the selected growth of the TMD channel layer 20 in the bottom where no inhibition layer 61 exists. In this way, the width uniformity of the TMD channel layer 20 is improved.

After the forming of a TMD channel, nitride layers in the stacked structure 15 are removed, and metal layers (i.e., word lines) are formed in regions where the nitride layers were removed from.

With the inhibition layer 61 being used to inhibit growth of the TMD on a surface of the inhibition layer, as the TMD deposits, it frequently has a bottom portion which is thinner than an upper portion as shown in the left-side depiction in FIG. 3A. To compensate, the TMD deposition is stopped, and an inhibition layer 61 is deposited (e.g. on the upper surface of the TMD layer 20). Afterwards, the TMD deposition continues with no deposition of TMD on the inhibition layer 61 as shown in the right-side depiction FIG. 3A. In one embodiment of the present disclosure, if the TMD deposition is stopped at the point in time shown in the right-side depiction in FIG. 3A, the macaroni structure (or hollow tube structure) of TMD can be realized. In another embodiment of the present disclosure, as shown FIG. 3B, an inhibition layer 61 can be deposited from the top to bottom of the sidewall of memory structure 30. Afterwards as shown in FIGS. 3C and 3D, a full channel of TMD 20 can be formed by TMD growth from bottom up from an exposed substrate/film at the bottom of the structure.

### Bit Line Formation

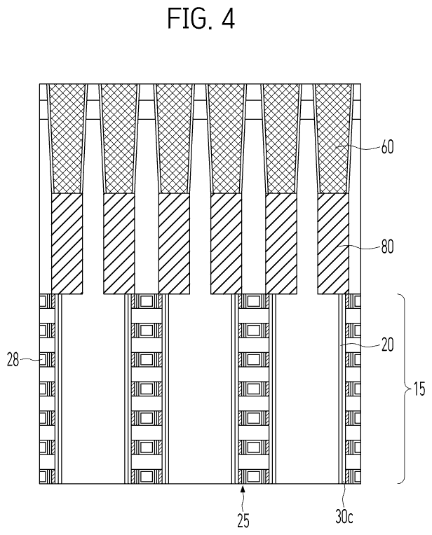

In one embodiment of the present disclosure, the TMD channel 20 can be contacted using a bit line contact 90 formation though a poly-silicon plug 80 as shown in FIG. 4. Here, as shown in FIG. 4, nitride layers in a prior intermediate stacked structure were removed, and metal layers (i.e., word lines) 28 were formed in regions where the nitride layers were removed from, forming in one embodiment of the present disclosure pocketed structure 25 where the above-noted first and second layers 30a and 30b are recessed.

The present disclosure is not limited to the kind of bit line contact materials used. The present disclosure is not limited to the ways that the bit line contacts and the poly-silicon plugs are made. The flow of electrons or charge carriers in the TMD channel layer 20 is controlled by driving word lines with a voltage. The cell string current (along the TMD channel 20 across multiple of the word lines WL) is enhanced by use of the TMD instead of poly-silicon for the channel.

### Formation Methods

In one embodiment of the present disclosure, there is provided a method of forming a TMD channel which utilizes selective epitaxial growth to selectively deposit a TMD channel deposition.

In another embodiment of the present disclosure, there is provided a method of forming a TMD channel which utilizes selective inhibition deposition to selectively deposit a TMD channel deposition.

These methods permit different types of channel structure (i.e., macaroni or full channel) or selected channel deposition to improve the word line width uniformity as a way to compensate different integration challenges which otherwise occur near the bottom of the channel layer due to for example a HAR etch difficulty.

In another embodiment of the present disclosure, the inhibition layer 61 can be used to mitigate integration challenges related to structural differences between top, middle and bottom sections of a stacked memory structure from process limitations or technical challenges (such as for example the HAR etch difficulty noted above). For example, due to smaller critical dimensions on bottom structures of a stacked memory cell, typically a lower thickness for the TMD is required for the bottom structures. By using the inhibition layer 61 to control where selective deposition takes place and by controlling how much TMD is selectively deposited, the thickness of a selected region can be controlled to improve overall cell-to-cell film stack uniformity and also to improve the overall cell characteristics.

In addition, a TMD channel can be contacted using bit line contact formation with poly silicon plugs and with the conductivity of the TMD providing the capability to accommodate more tiers for active cells (i.e., that is provide higher cell densities). The present invention provides an effective method that allows continuous cell string current improvement without thickness scaling limitation.

In another embodiment, a TMD channel may include use of bit line contact formation using poly-Si plug and the overall contact depth can be further reduced to accommodate more tiers for active cells for higher cell density.

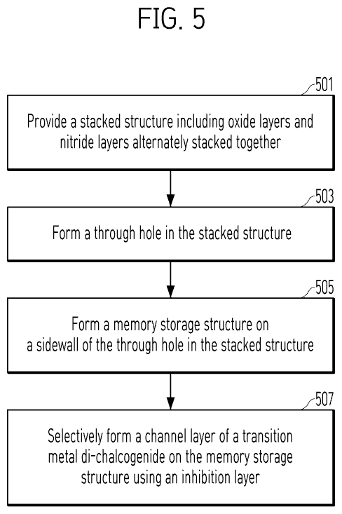

FIG. 5 is a flowchart illustrating exemplary processes used in the present disclosure to form a 3D memory device. At 501, the method for forming a memory storage structure may provide a stacked structure including oxide layers and nitride layers alternately stacked together. At 503, the method may form a through hole in the stacked structure. At 505, the method may form a memory storage structure on a sidewall of the through hole in the stacked structure. At 507, the method may selectively form a channel layer of a semiconductive transition metal di-chalcogenide on the memory storage structure using an inhibition layer. In one method embodiment, the selectively forming of the channel layer may comprise depositing a seed layer on the memory storage structure.

In one method embodiment, the selectively forming of the channel layer may include depositing a hollow tube of the transition metal di-chalcogenide on the memory storage structure. This hollow tube structure (e.g., including the TMD macaroni channel 10 shown in FIG. 1) can be deposited with or without use of the inhibition layer.

In one method embodiment, the selectively forming of the channel layer may include completely filling the through hole with the transition metal di-chalcogenide. This completely full through hole structure (e.g., including the TMD full channel 50 shown in FIG. 2) can be deposited with or without use of the inhibition layer.

In one method embodiment, the selectively forming of the channel layer may include selectively inhibiting where the transition metal di-chalcogenide deposits.

In one method embodiment, the selectively inhibiting may include depositing the inhibition layer on the memory storage structure on the sidewall of the through hole in the stacked structure.

In one method embodiment, the selectively forming of the channel layer may include forming a first transition metal di-chalcogenide layer on the memory storage structure on the sidewall of the through hole in the stacked structure. The selectively inhibiting may include depositing the inhibition layer on an upper part of the first transition metal di-chalcogenide layer. The inhibition layer may include at least one or more self-assembling monolayers.

In one method embodiment, the method may further include depositing a second transition metal di-chalcogenide layer on a lower part of the first transition metal di-chalcogenide layer.

In one method embodiment, the method may further include forming a word line in the stacked structure and forming a bit line contact plug connected to the channel layer of the transition metal di-chalcogenide.

In one method embodiment, the word line, the stacked structure with the bit line contact, the channel layer including the transition metal di-chalcogenide, and the memory storage structure may form the 3D memory device (e.g., a 3D NAND).

In one method embodiment, nitride layers in the stacked structure are removed, and metal layers (i.e., word lines) are formed in regions where the nitride layers were removed from. That is, this method embodiment involves removing at least a part of the nitride layers from the stacked structure, and forming word lines in the stacked structure in regions where the nitride layers were removed.

In one method embodiment, the method may further include removing at least a part of the nitride layers from the stacked structure and forming word lines in the stacked structure in regions where the nitride layers were removed.

### TMD Memory Devices

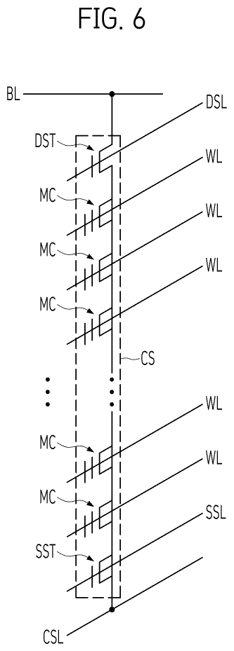

FIG. 6 illustrates a single memory cell string CS, but a plurality of memory cell strings may be coupled in parallel between the bit line BL and the common source line CSL. The memory cell string CS may include a source select transistor SST, a plurality of memory cells MC, and a drain select transistor DST disposed between the common source line CSL and the bit line BL. Each of the memory cells MC may include one of the memory structures described above with reference to FIGS. 1-4.

The source select transistor SST may control the electrical coupling between the plurality of memory cells MC and the common source line CSL. A single source select transistor SST may be disposed between the common source line CSL and the plurality of memory cells MC. Two or more source select transistors SST coupled in series to each other may be disposed between the common source line CSL and the plurality of memory cells MC. The source select transistor SST may be coupled to a source select line SSL. The operation of the source select transistor SST may be controlled by a source gate signal applied to the source select line SSL.

The plurality of memory cells MC may be disposed between the source select transistor SST and the drain select transistor DST. The memory cells MC between the source select transistor SST and the drain select transistor DST may be coupled in series to each other. The memory cells MC may be coupled to respective word lines WL. The operation of the memory cells MC may be controlled by cell gate signals applied to the word lines WL.

The drain select transistor DST may control the electrical coupling between the plurality of memory cells MC and the bit line BL. The drain select transistor DST may be coupled to a drain select line DSL. The operation of the drain select transistor DST may be controlled by a drain gate signal applied to the drain select line DSL. Each of the memory cells MC may store single-bit data or multi-bit data.

Referring to FIG. 7, the semiconductor memory device of the present invention may include a stacked body 100, a channel layer 127 (corresponding to TMD channel layers 20 in FIGS. 1-4), a tunnel insulating layer 125 (corresponding to 30c in FIG. 1), a data storage layer 123 (corresponding to 30b in FIG. 1), and a blocking insulating layer 121 (corresponding to 30a in FIG. 1).

The stacked body 100 may include interlayer insulating layers 101 and word lines 103 in contact with blocking insulator 121. Each of the interlayer insulating layers 101 and the word lines 103 may be parallel to an X-Y plane. The interlayer insulating layers 101 and the word lines 103 may be stacked in a Z-axis direction perpendicular to the X-Y plane. The interlayer insulating layers 101 may be disposed alternately with the word lines 103. In one embodiment, TMD layer 125 extends over oxide layer 101 at the top of stack 100 to provide more contact area for poly-silicon plug 80.

The word lines 103 may be insulated from each other by the interlayer insulating layers 101. The word lines 103 may be used as the gate electrodes of the memory cells MC described with reference to FIG. 1. The word lines 103 may include at least one of a doped semiconductor, metal, a metal nitride, and a metal silicide. The interlayer insulating layers 101 may include a silicon oxide layer.

The stacked body 100 may be penetrated by a hole 111 extending in the Z-axis direction. The sidewalls of the interlayer insulating layers 101 may be defined along the sidewall of the hole 111. Oxide 129 can fill the space in hole 111.

FIG. 8 depicts another embodiment where the holes 111 are elongated or oval opening. In this embodiment, the TMD channel 127 can be cut to permit MSC devices to be formed along the longer axis of each elongated hole 111 to increase the density of memory cells. The other details of FIG. 8 are the same as given for FIG. 7.

Accordingly, in one embodiment of the present invention, there is provided a 3D semiconductor memory device. The 3D semiconductor memory device may include a stacked dielectric structure having a through hole; a memory storage structure disposed on a sidewall of the through hole in the stacked structure; a channel layer of a semiconductive transition metal di-chalcogenide disposed on the memory storage structure; and an inhibition layer disposed on a part of the channel layer. In one embodiment, the inhibition layer comprises a material which inhibits growth of the semiconductive transition metal di-chalcogenide on a surface of the inhibition layer.

In one device embodiment, the channel layer may include a hollow tube of the semiconductive transition metal di-chalcogenide.

In one device embodiment, the channel layer may include a full channel layer filling the through hole of stacked dielectric structure.

In one device embodiment, the semiconductive transition metal di-chalcogenide may include at least one or more of molybdenum disulfide (MoS₂), Tungsten disulfide (WS₂), molybdenum diselenide (MoSe₂), molybdenum telluride (MoTe₂), tin sulfide (SnS₂), tin selenide (SnSe₂), hafnium sulfide (HfS₂), hafnium selenide (HfSe₂), platinum sulfide (PtS₂), platinum selenide (PtSe₂), platinum telluride (PtTe₂) and Tungsten diselenide (WSe₂).

In one device embodiment, the inhibition layer includes at least one or more self-assembling monolayers.

In one device embodiment, the inhibition layer may be disposed on a surface of an upper part of the memory storage structure formed to control a nucleation density of the semiconductive transition metal di-chalcogenide.

In one device embodiment, the 3D semiconductor memory device may further include a word line disposed in the stacked structure and a bit line contact plug connected to the channel layer of the semiconductive transition metal di-chalcogenide.

In one device embodiment of the present disclosure, there is provided a 3-dimensional (3D) semiconductor memory device having a stacked structure comprising oxide layers and nitride layers alternately stacked together; a through hole in the stacked structure; a memory storage structure on a sidewall of the through hole in the stacked structure; and a channel layer of a transition metal di-chalcogenide on the memory storage structure, wherein the memory device comprises multiple cells forming a stacked NAND device and the channel layer of the transition metal di-chalcogenide comprises a NAND channel layer contacting memory storage structures in the multiple cells.

In another device embodiment of the present disclosure, there is provided a 3-dimensional (3D) semiconductor memory device having a stacked structure comprising oxide layers and nitride layers alternately stacked together; a through hole in the stacked structure; a memory storage structure on a sidewall of the through hole in the stacked structure; and a channel layer of a transition metal di-chalcogenide (TMD) on the memory storage structure, wherein the channel layer fills the through hole and comprises a full channel TMD structure. The present inventors have realized that there are challenges in implementing full channel structure in a 3D semiconductor memory device using silicon channels because of the trap density due to dangling bonds and grain boundary traps in poly Si is too high. Here, for this embodiment, where TMD (a material having a lower trap density) is used for the full channel, this issue is addressed.

Although the foregoing embodiments have been described in some detail for purposes of clarity of understanding, the invention is not limited to the details provided. There are many alternative ways of implementing the invention. The disclosed embodiments are illustrative and not restrictive. The present invention is intended to embrace all modifications and alternatives of the disclosed embodiment. Furthermore, the disclosed embodiments may be combined to form additional embodiments.

While this patent document contains many specifics, these should not be construed as limitations on the scope of any invention or of what may be claimed, but rather as descriptions of features that may be specific to particular embodiments of particular inventions.

What is claimed is:

1. A method for forming a 3-dimensional (3D) semiconductor memory device, the method comprising:
providing a stacked structure comprising oxide layers and nitride layers alternately stacked together;
forming a through hole in the stacked structure;
forming a memory storage structure on a sidewall of the through hole in the stacked structure; and
selectively forming a channel layer of a transition metal di-chalcogenide on the memory storage structure using an inhibition layer.

2. The method of claim 1, wherein the selectively forming of the channel layer comprises depositing a seed layer on the memory storage structure.

3. The method of claim 1, wherein the selectively forming of the channel layer comprises depositing a hollow tube of the transition metal di-chalcogenide on the memory storage structure.

4. The method of claim 2, further comprising additionally forming the transition metal di-chalcogenide to completely fill the through hole.

5. The method of claim 1, wherein the selectively forming of the channel layer comprises selectively inhibiting where the transition metal di-chalcogenide deposits.

6. The method of claim 5, wherein the selectively inhibiting comprises depositing the inhibition layer on the memory storage structure on the sidewall of the through hole in the stacked structure.

7. The method of claim 5, wherein:
the selectively forming of the channel layer comprises forming a first transition metal di-chalcogenide layer on the memory storage structure on the sidewall of the through hole in the stacked structure; and
the selectively inhibiting comprises depositing the inhibition layer on an upper part of the first transition metal di-chalcogenide layer.

8. The method of claim 7, further comprising depositing a second transition metal di-chalcogenide layer on a lower part of the first transition metal di-chalcogenide layer.

9. The method of claim 1, further comprising:
forming a word line in the stacked structure; and
forming a bit line contact plug connected to the channel layer of the transition metal di-chalcogenide.

10. The method of claim 9, wherein the word line, the stacked structure with the bit line contact, the channel layer comprising the transition metal di-chalcogenide, and the memory storage structure form the 3D memory device.

11. The method of claim 1, wherein the transition metal di-chalcogenide comprises at least one or more of molybdenum disulfide (MoS₂), Tungsten disulfide (WS₂), molybdenum diselenide (MoSe₂), molybdenum telluride (MoTe₂), tin sulfide (SnS₂), tin selenide (SnSe₂), hafnium sulfide (HfS₂), hafnium selenide (HfSe2), platinum sulfide (PtS₂), platinum selenide (PtSe), platinum telluride (PtTe₂) and Tungsten diselenide (WSe₂).

12. The method of claim 7, the inhibition layer comprises at least one or more self-assembling monolayers.

13. The method of claim 1, further comprising:
removing at least a part of the nitride layers from the stacked structure; and
forming word lines in the stacked structure in regions where the nitride layers were removed.

14. A 3D semiconductor memory device comprising:
a stacked dielectric structure having a through hole;
a memory storage structure disposed on a sidewall of the through hole in the stacked structure;
a channel layer of a semiconductive transition metal di-chalcogenide disposed on the memory storage structure; and
an inhibition layer disposed on a part of the channel layer, wherein the inhibition layer comprises a material which inhibits growth of the semiconductive transition metal di-chalcogenide on a surface of the inhibition layer.

15. The 3D semiconductor memory device of claim 14, wherein the channel layer comprises a hollow tube of the semiconductive transition metal di-chalcogenide.

16. The 3D semiconductor memory device of claim 14, wherein the channel layer comprises a full channel layer filling the through hole of stacked dielectric structure.

17. The 3D semiconductor memory device of claim 14, wherein the semiconductive transition metal di-chalcogenide comprises at least one or more of molybdenum disulfide (MoS₂), Tungsten disulfide (WS₂), molybdenum diselenide (MoSe₂), molybdenum telluride (MoTe₂), tin sulfide (SnS₂), tin selenide (SnSe₂), hafnium sulfide (HfS₂), hafnium selenide (HfSe2), platinum sulfide (PtS₂), platinum selenide (PtSe), platinum telluride (PtTe₂) and Tungsten diselenide (WSe₂).

18. The 3D semiconductor memory device of claim 14, wherein the inhibition layer comprises at least one or one or more self-assembling monolayers.

19. The 3D semiconductor memory device of claim 18, wherein the inhibition layer is disposed on a surface of an upper part of the memory storage structure formed to control a nucleation density of the semiconductive transition metal di-chalcogenide.

20. The 3D semiconductor memory device of claim 14, further comprising:
a word line disposed in the stacked structure; and
a bit line contact plug connected to the channel layer of the semiconductive transition metal di-chalcogenide.
